(19) United States
(12) Patent Application Publication
(10) Pub. No.: US 2006/0134563 A1
(43) Pub. Date: Jun. 22, 2006

(54) Method for manufacturing semiconductor device

(76) Inventor: Minoru Watanabe, Tokyo (JP)

Correspondence Address: RABIN & BERDO, P.C., Suite 500, 1101 14th Street, Washington, DC, 20005, US

(21) Appl. No.: 11/209,751

(22) Filed: Aug. 24, 2005

(30) Foreign Application Priority Data
Dec. 22, 2004 (JP) 372037/2004

(51) Int. Cl. G03F 7/00

(52) U.S. Cl. 430/322

(57) ABSTRACT

The present invention provides a method for manufacturing a semiconductor device, which includes a resist deposition step for forming a resist film on the surface of a semiconductor substrate provided with a plurality of chips disposed in matrix form, an exposure step for sequentially exposing chip patterns with respect to the respective chips in a predetermined exposure order from the chip set as a starting point of the semiconductor substrate, and a development step for developing the respective chips in the order opposite to the exposure order from the chip set as an end point in the exposure order.

### BACKGROUND OF THE INVENTION

1. Field of the Invention

The present invention relates to a method for manufacturing a semiconductor device, and particularly to a method for manufacturing a semiconductor device, which effects post-exposure development processing on a substrate such as a semiconductor wafer.

2. Description of the Related Art

In recent years, an exposure technique in which an excimer laser short in exposure wavelength and a high-sensitive chemical amplifying resist are utilized in combination, has widely been used in a lithography process for performing pattern formation of a semiconductor device, in order to adapt to high integration and micro-fabrication of the semiconductor device. The chemical amplifying resist is equivalent to one in which acid produced in the resist by exposure is diffused in the resist and a dissolution inhibiting agent contained in the same resist is decomposed to allow an exposure part to be soluble in a developing solution or developer. On the other hand, a scan system wherein in order to solve the difference in the amount of delivery of a developer between a central portion of a wafer and its peripheral portion, the developer is delivered while a developer supply nozzle is being scanned on the wafer, thereby to apply the developer onto the wafer, is being adopted for post-exposure development processing.

The inventions related to lithography of the semiconductor device have been described in, for example, the following patent documents.

The invention described in Japanese Patent Application No. Hei 9(1997)-237745 (see pp 3-5 and FIG. 1) relates to a method for performing pattern formation using a chemical amplifying resist, which upon exposure of a plurality of wafers, measures a change in sensitivity per unit time, of the resist under respective environments under which the wafers are left, i.e., under respective environments of (1) they are left in vacuum before exposure, (2) they are left in vacuum after exposure, (3) they are left in the atmosphere before exposure and (4) they are left in the atmosphere after exposure, calculates the optimum amount of exposure with the sensitivity change and time intervals taken for their leaving being defined as parameters and adjusts or controls the amount of exposure between the wafers or in the wafer. Thus, variations in dimension between the wafers or in the wafer are suppressed.

The invention described in Japanese Patent Application No. 2001-57334 (see pp 6-9 and FIG. 7) is one wherein a developer supply nozzle is scanned on a wafer twice or more to apply a developer and thereby a developer paddle formed on the wafer by the first scan is stirred by the delivery of a developer by a scan of the second time or later. Thus, development processing is evenly performed and hence the uniformity of pattern dimensions is improved.

The invention described in Japanese Patent Application No. 2003-272991 (see pp 4-6 and FIG. 1) relates to a method for performing pattern formation using a chemical amplifying resist, which calculates an exposure process tact time on the basis of information from an exposure device, i.e., wafer-surface illumination information, compares the exposure process tact time, an application process tact time and a development process tact time and adjusts a resist application process tact time according to the relationship of magnitude among the three. Thus, process processing times for respective wafers are held constant and variations in dimension between the wafers or in the wafer are suppressed.

Although the chemical amplifying resist is of a material very effective for miniaturization of the semiconductor wafer, it contains several dimension variable factors in terms of its property. The first variable factor is deactivation of acid due to a neutralization reaction with a basic substance in the atmosphere, e.g., ammonia (NH₃) or the like. Since the chemical amplifying resist makes use of acid produced by photochemical reaction as already mentioned, the decomposition of a dissolution inhibiting agent becomes hard to occur in the surface of the resist when such acid makes a neutralization reaction with the basic substance in the atmosphere and is deactivated. Further, its surface becomes hard to dissolve so that a variation in pattern dimension becomes easy to take place. Therefore, a chemical filter is used within an area in a clean room which treats the chemical amplifying resist, in order to remove the basic substance in the atmosphere. Further, the formation of a protective film having acidic on the surface of the chemical amplifying resist, etc. have been performed. The second variable factor is diffusion of acid produced in the resist by exposure. The acid produced by exposure is gradually diffused into the resist in a draw-and-lay time from after exposure up to post bake, so-called PEB (Post Exposure Bake) and decomposes the dissolution inhibiting agent over a range wider than an exposure area. As a result, a line-width dimension of each pattern greatly decreases with respect to a desired value. A dimension varying phenomenon due to such two variable factors, i.e., the deactivation of acid and its diffusion is generally called “PED (Post Exposure bake Delay effect)”.

As to the dimension variation due to the deactivation of acid in PED, its influence can be kept to a minimum by use of the chemical filter, the protective film or the like. As to the dimension variation due to the diffusion of acid, however, it greatly depends on the draw-and-lay time from after exposure up to PEB. It was therefore difficult to suppress its influence. It was particularly difficult to solve a difference in draw-and-lay time in the same wafer, i.e., a difference in pattern dimension that occurs due to a difference in draw-and-lay time caused by an exposure order in the wafer.

On the other hand, it is known that development processing relates to the dependence of pattern dimensions of a resist on a developing time. Although generally slow as compared with a solution rate of an exposure area in the case of a resist, a non-exposure area is also gradually dissolved with a developing solution or developer. In particular, a boundary portion between the exposure area and the non-exposure area becomes more soluble. Therefore, there is a tendency that as the developing time, i.e., the time from the putting of the developer onto a wafer up to before a post-development rinse process becomes long, the pattern dimensions decrease. Thus, the development processing of the scan system causes a difference in pattern dimension in the same wafer depending on a scan direction and a scan speed.

The invention described in Japanese Patent Application No. Hei 9(1997)-237745 aims to solve variations in dimension due to PED by means of exposure processing and is not intended for execution of specially-set processing about development.

The invention described in Japanese Patent Application No. 2001-57334 aims to uniformly apply a developing solution or developer by scanning a developer supply nozzle plural times and is not intended for resolution of variations in dimension due to PED by development processing.

The invention described in Japanese Patent Application No. 2003-272991 aims to solve variations in dimension due to PED by adjusting a tact time for a resist application process and is not intended for execution of specially-set processing about development.

### SUMMARY OF THE INVENTION

With the foregoing in view, it is an object of the present invention to provide a method for manufacturing a semiconductor device, which is capable of reducing a difference between pattern dimensions in a wafer surface due to PED (Post Exposure bake Delay effect).

According to one aspect of the present invention, for achieving the above object, there is provided a method for manufacturing a semiconductor device, comprising a resist deposition step for forming a resist film on the surface of a semiconductor substrate provided with a plurality of chips disposed in matrix form, an exposure step for sequentially exposing chip patterns with respect to the respective chips in a predetermined exposure order from the chip set as a starting point of the semiconductor substrate, and a development step for developing the respective chips in the order opposite to the exposure order from the chip set as an end point in the exposure order.

According to the method for manufacturing the semiconductor device, according to the present invention, development processing is carried out in the order opposite to an exposure order. Thus, for example, differences in dimension among resist patterns due to PED (diffusion) in a wafer can be canceled out by the development processing. Consequently, differences in pattern dimension in the same wafer can be reduced.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a chip layout diagram showing a semiconductor wafer;

FIG. 2 is a diagram illustrating variations in gate dimension in the semiconductor wafer due to PED (diffusion);

FIG. 3 is a diagram depicting the dependence of gate dimensions on development time;

FIG. 4 is a diagram showing differences among the gate dimensions in the semiconductor wafer subsequent to development processing;

FIG. 5 is a diagram illustrating a scan direction of a developer supply nozzle employed in a method for manufacturing a semiconductor device, according to one embodiment;

FIG. 6 is a plan schematic diagram showing a development processing apparatus for realizing the method for manufacturing the semiconductor device, according to the one embodiment; and

FIG. 7 is a sectional schematic diagram illustrating the development processing apparatus for realizing the method for manufacturing the semiconductor device according to the one embodiment.

### DETAILED DESCRIPTION OF THE PREFERRED EMBODIMENTS

One embodiment of the present invention will be explained while taking, as an example, a case in which the present invention is applied to a process for forming the gate of a transistor.

[Development Processing Method]

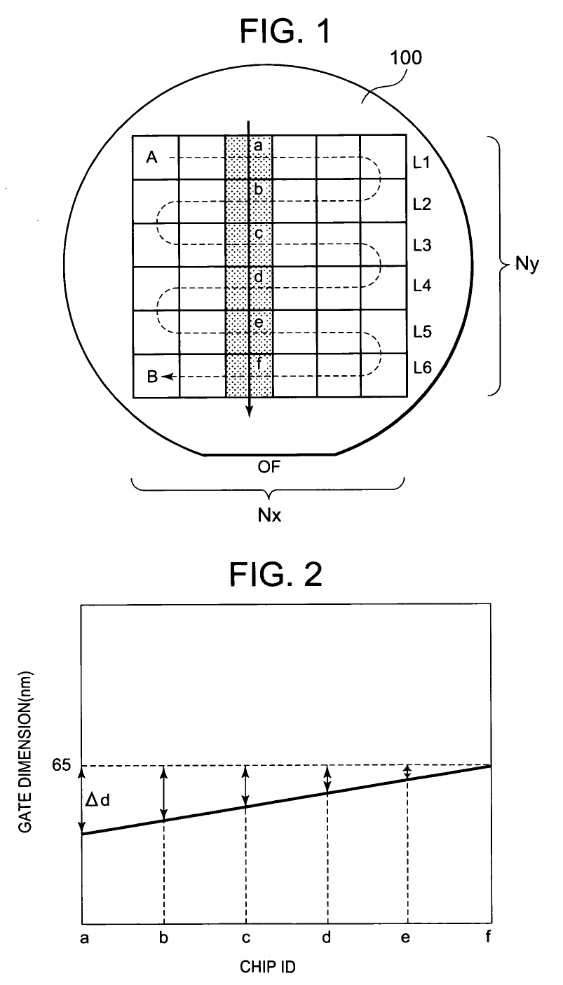

Now consider where a semiconductor wafer 100 has such a 6×6 chip layout as shown in FIG. 1 by way of example, which is made on its main surface. That is, the semiconductor wafer 100 is provided with 36 chips equivalent to the sum of the number of chips in an X-axis direction Nx=6 and the number of chips in a Y-axis direction Ny=6. And the respective chips respectively include integrated circuits formed by semiconductor elements such as transistors, etc.

A process up to PEB subsequent to execution from resist application to exposure in the present embodiment is similar to the normal photolithography. Described briefly, polysilicon corresponding to a gate electrode material is first formed over the whole area of the semiconductor wafer 100. Thereafter, a chemical amplifying resist for pattern formation is spin-coated on the polysilicon with BARC (Bottom Anti-Reflective Coating) corresponding to an antireflection film interposed therebetween. The thickness of the chemical amplifying resist is assumed to be 290 nm, for example. Then, pre-bake is carried out on a hot plate under the condition of 120° C./90 sec and thereafter exposure processing is effected. The exposure processing makes use of excimer laser as a light source and is stepped-and-repeated from a chip A to a chip B in the order indicated by a broken line as shown in FIG. 1. Subsequently, PEB is done on the hot plate under the condition of 110° C./90 sec to cause acid catalysis for an exposure area.

Meanwhile, as already mentioned, the chemical amplifying resist is accompanied by the problem that the line-width dimensions of the patterns decrease due to the acid diffusion produced during a draw-and-lay time thereof from after PED, especially, exposure up to PEB. FIG. 2 shows, as one example, a tendency toward variations in pattern dimensions, i.e., gate dimensions of respective chips (FIG. 1) denoted at a to f, of the semiconductor wafer 100 due to PED (diffusion). Incidentally, the gate dimensions shown in FIG. 2 show where development processing is effected on the entire surface of the semiconductor wafer 100 in gross (it is not the scan system), i.e., where the processing is effected on the respective chips indicated by a to f under the same development conditions. That is, the variations in the gate dimensions in FIG. 2 show only the influence of the dimensional variations due to PED (diffusion). Referring to FIG. 2, the dimension gradually decreases from the chips f to a with respect to a target dimension 65 nm. Since the exposure processing of the semiconductor wafer 100 is done in the order indicated by the broken line in FIG. 1 in the present embodiment, the draw-and-lay time from after exposure up to PEB becomes gradually short from the chips a to f. Thus, if only the influence of PED (diffusion) is taken into consideration, then the dimension of the chip a long in draw-and-lay time becomes shortest, and the dimension of the chip f short in draw-and-lay time becomes a desired design value, i.e., a dimension close to 65 nm.

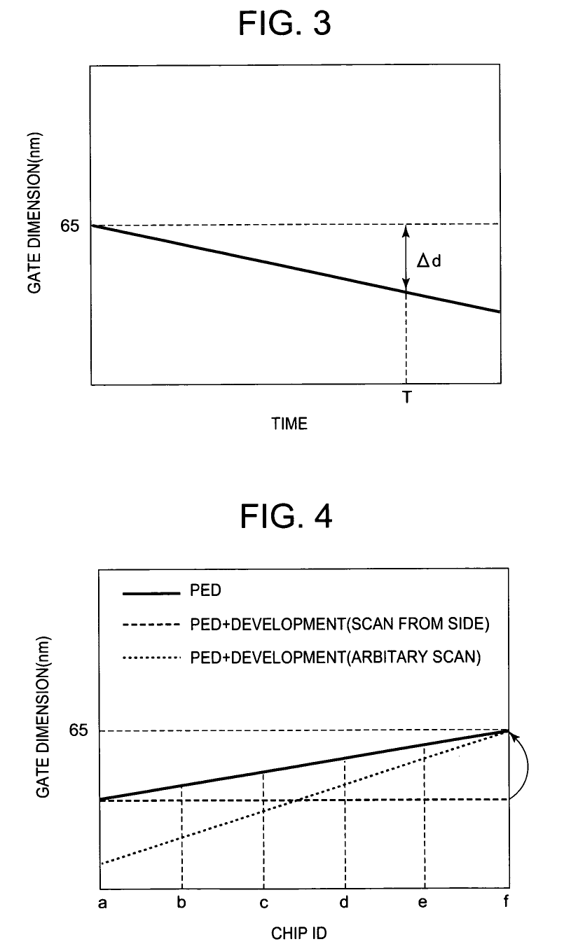

Next, development processing is effected on the semiconductor wafer 100 that has completed PEB. In general, as already mentioned, the development processing is accompanied by the problem that the pattern dimension decreases as the developing time becomes long. FIG. 3 shows the relationship between the pattern dimensions, i.e., gate dimensions of the semiconductor wafer 100 and a developing time as one example. Incidentally, the gate dimensions in FIG. 3 show where they are not affected by a draw-and-lay time of a resist. That is, variations in gate dimension in FIG. 3 indicate only the influence of the developing time. Upon data acquisition of FIG. 3, for example, a plurality of wafers subjected to exposure processing under the same conditions using a chemical amplifying resist are prepared. The respective wafers are processed in different developing times in a state in which draw-and-lay times of the respective wafers are hold constant. Thus, even when the chemical amplifying resist is used, data can be obtained which have excluded the influence of variations in dimension due to PED (diffusion). It is understood that referring to FIG. 3, the pattern dimension, i.e., the gate dimension becomes small as the developing time becomes long. Thus, if only the influence of the developing time is taken into consideration, then the amount of change in pattern dimension depends on the direction of scanning of a developer supply nozzle and its scan speed in the case of the development processing of the scan system.

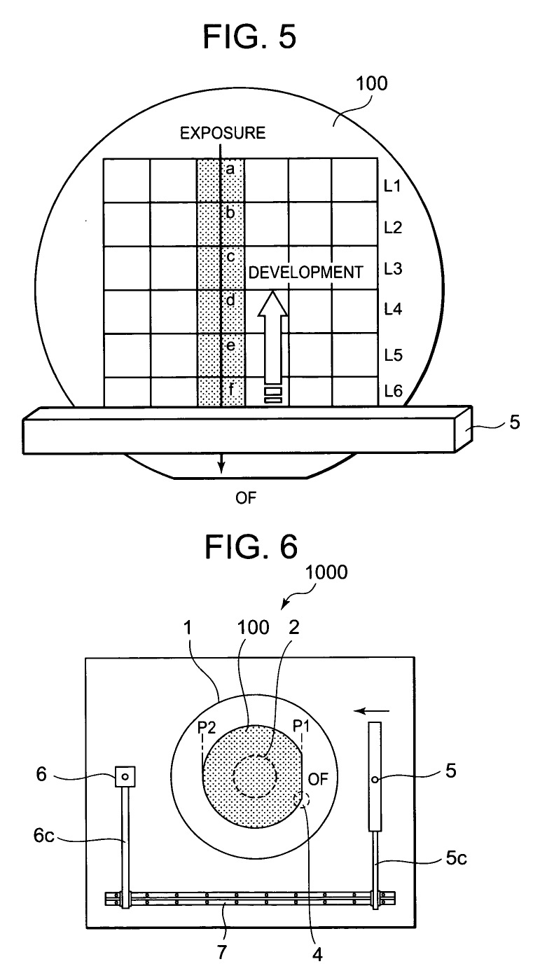

Therefore, the present invention is characterized in that the development processing is performed from the chip side in which the draw-and-lay time from after exposure up to PEB is short, i.e., the chip side in which exposure processing is finally carried out. In particular, the development processing method of the scan system is characterized in that the scan direction of the developer supply nozzle is adjusted in such a manner that the development processing is carried out from the chip side in which exposure has finally been performed. Since the exposure processing is performed from a first line L1 to a sixth line L6 of the semiconductor wafer 100 as shown in FIG. 1 in the present embodiment, the direction of scan of a developer supply nozzle 5 is adjusted such that development processing in this case is performed form the orientation flat (OF) side near a sixth line L6 as shown in FIG. 5. Incidentally, a scan speed at this time is set in the following manner on the basis of the correlation between the gate dimensions and developing time shown in FIG. 3, for example. When the difference between the gate dimensions in the same wafer due to PED (diffusion), e.g., the difference in gate dimension between the chips a and f in the semiconductor wafer 100 is now Ad as shown in FIG. 2, a developing time T equivalent to the difference in gate dimension Ad is determined from the relation of FIG. 3. And the scan speed is set in such a manner that a scan time from a starting point of a development scan to its end point, i.e., from the sixth line L6 side to which the chip f belongs to the first line L1 side to which the chip a belongs becomes T. Thus, the substantial developing time on the sixth line L6 side to which the chip f belongs, can be prolonged by T. In other words, the dimension of the chip f can be thinned by Δd.

FIG. 4 shows differences in pattern dimension among the respective chips (FIG. 1) designated at a to f of the semiconductor wafer 100, i.e., differences in gate dimension subsequent to development processing. A solid line indicates the differences in gate dimension (same as FIG. 2) due to the influence of PED (diffusion) alone. A broken line indicates the differences in gate dimension where a development processing method according to the present invention is effected on the semiconductor wafer 100 placed under the influence of PED (diffusion), i.e., the scan direction of the developer supply nozzle 5 is adjusted so as to be set from the chip side short in draw-and-lay time to apply development processing. In the present embodiment, the developer supply nozzle 5 is scanned from the orientation flat (OF) side of the semiconductor wafer 100. A dotted line indicates the maximum differences in gate dimension where a conventional development processing method is effected on the semiconductor wafer 100 placed under the influence of PED (diffusion), i.e., the developer supply nozzle 5 is scanned from the direction arbitrary with respect to the wafer to apply development processing. Incidentally, FIG. 4 shows the results all placed under the same exposure conditions.

When the developer supply nozzle 5 is scanned from the direction arbitrary with respect to the semiconductor wafer 100 as in the conventional development processing method, the scan direction differ for each wafer. Therefore, when a development scan is started from the chip side long in draw-and-lay time from after exposure up to PEB, i.e., the chip side in which exposure has first been done, the difference in gate dimension between the chips due to PED (diffusion) further increases with development processing. When, for example, the developer supply nozzle 5 is scanned with respect to the semiconductor wafer 100 exposed in the order such as shown in FIG. 1 from the side opposite to the orientation flat (OF), the dimension of the chip a long in draw-and-lay time and developing time becomes thinner as indicated by the dotted line of FIG. 4, thereby increasing the inclination of a straight line. That is, the differences in gate dimension among the chips a through f increase.

On the other hand, when the scan direction of the developer supply nozzle 5 is adjusted in such a manner that the development processing is started from the chip side short in draw-and-lay time with respect to the semiconductor wafer 100 as in the development processing method according to the present invention, each chip short in draw-and-lay time is set long in developing time, and each chip long in draw-ant-lay time is set short in developing time. Therefore, the differences in gate dimension among the chips due to PED (diffusion) are canceled out by the development processing. When, for example, the developer supply nozzle 5 is scanned with respect to the semiconductor wafer 100 exposed in the order such as shown in FIG. 1 from the side of the orientation flat (OF), the dimension of the chip f long in developing time becomes thin as indicated by the broken line of FIG. 4, thereby decreasing the inclination of a straight line. That is, the differences in gate dimension among the chips a through f decrease and hence the gate dimensions are uniformized within the same wafer. Incidentally, although the absolute values of the gate dimensions subsequent to the development processing are transitioned thin with respect to the target value 65 nm in FIG. 4, the dimensional level of the entire wafer can be finished to the neighborhood of the target value 65 nm by adjusting the amount of exposure.

[Development Processing Apparatus]

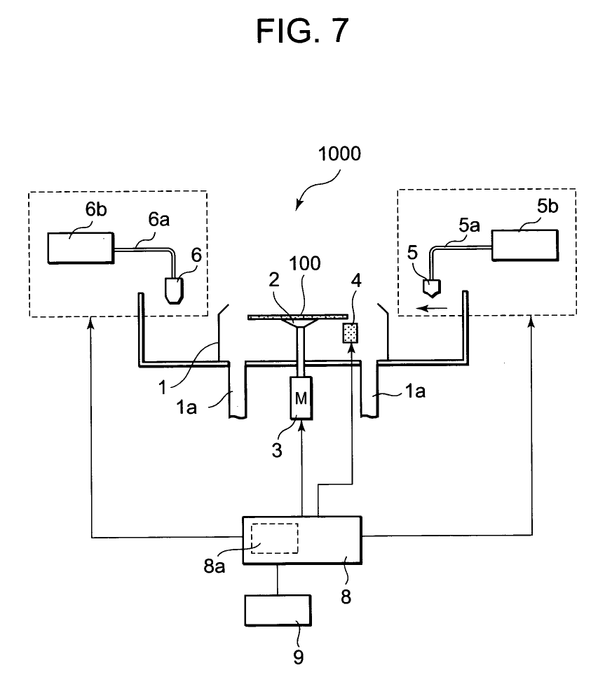

FIGS. 6 and 7 are respectively schematic configurational diagrams showing a development processing apparatus 1000 for realizing a development processing method according to the present invention. FIG. 6 is a plan view thereof as viewed from above, and FIG. 7 is a sectional view thereof, respectively.

An annular cup 1 is disposed in the center of the development processing apparatus 1000. Waste liquid pipes la for discharging a developer and a cleaning or rinse solution are provided at the bottom of the cup 1. A spin chuck 2 for holding a semiconductor wafer 100 is disposed inside the cup 1. The spin chuck 2 is rotatably driven by a driving motor 3 in a state in which the semiconductor wafer 100 is fixed and held by vacuum suction. A detector 4 is a sensor for detecting an orientation flat (OF) or a notch indicative of a plane direction of the semiconductor wafer 100. The detector 4 is disposed in the neighborhood of the semiconductor wafer 100. A developer supply nozzle 5 is a nozzle for supplying a developing solution or developer to the surface of the semiconductor wafer 100. The developer supply nozzle 5 is shaped long and disposed with its longitudinal direction as the horizon, and is connected to a developer supply section 5b via a developer supply pipe 5a. Also the developer supply nozzle 5 is attached to its corresponding tip of a nozzle scan arm 5c. The nozzle scan arm 5c is horizontally movable on a guide rail 7 laid in one direction. A rinse nozzle 6 is a nozzle for supplying the cleaning or rinse solution to the surface of the semiconductor wafer 100 and is connected to a rinse solution supply section 6b via a rinse solution supply pipe 6a. Also the rinse nozzle 6 is attached to its corresponding tip of a nozzle scan arm 6c. The nozzle scan arm 6c is horizontally movable on the guide rail 7 laid in one direction. A controller 8 controls the driving motor 3 and the detector 4 and controls the operations of the developer supply nozzle 5 and the rinse nozzle 6 and the supply of the solutions from the developer supply section 5b and the rinse solution supply section 6b. Incidentally, a memory 8a, which stores a plurality of process recipes containing information about a scan direction and a scan speed of the developer supply nozzle 5 to be described later, and the direction of holding of the semiconductor wafer 100, etc., is provided inside the controller 8. A series of development processes are executed by a predetermined process recipe selected by a command issued from an operation unit 9.

The operation of the development processing apparatus 1000 according to the present invention will next be explained. The semiconductor wafer 100 in which predetermined patterns have been exposed and PEB has been executed, is first transferred to directly above the cup 1 by an unillustrated wafer transfer mechanism and adsorbed under vacuum by the spin chuck 2, followed by being held thereby.

Next, the driving motor 3 rotates and drives the spin chuck 2 in accordance with a command issued from the controller 8 to rotate the semiconductor wafer 100. When the detector 4 detects an orientation flat (OF) or a notch of the semiconductor wafer 100, the controller 8 controls the driving motor 3 to stop the spin chuck 2 at a predetermined position, e.g., a position where the orientation flat (OF) of the semiconductor wafer 100 is fixed and held so as to be parallel to the long-side part of the developer supply nozzle 5 as shown in FIG. 6, for example.

Next, the scan of the developer supply nozzle 5 is started from a predetermined direction in accordance with a command issued from the controller 8. Since the exposure processing is carried out from the side opposite to the orientation flat (OF) in the present embodiment, the direction of scanning of the developer supply nozzle 5 is set from the orientation flat (OF) side of the semiconductor wafer 100 to the side opposite to the orientation flat (OF), i.e., from P1 to P2 in FIG. 6. Incidentally, when the exposure processing is done from the orientation flat (OF) side, the scan direction of the developer supply nozzle 5 may be set from the side opposite to the orientation flat (OF) of the semiconductor wafer 100 to the orientation flat (OF) side, i.e., from P2 to P1 in FIG. 6. Such settings of the scan direction of the developer supply nozzle 5 can be made as process recipes of the development processing apparatus 1000 together with the settings of a scan speed, etc. It is thus possible to simply perform the optimum dimensional control according to products and processes.

Subsequent processes are similar to the normal development processing method. They will be described in brief. A developer is applied by scan and thereafter still development is done for a predetermined time. When the still development is completed, the semiconductor wafer 100 is rotated by the spin chuck 2 so that the developer is chucked off. Subsequently, the rinse nozzle 6 is moved onto the semiconductor wafer 100 to deliver the rinse solution, whereby the developer that remains on the semiconductor wafer 100 is washed away by the rinse solution. Thereafter, the semiconductor wafer 100 is rotated at high speed by the spin chuck 2, so that the developer and rinse solution that remain on the semiconductor wafer 100 are blown off to dry the semiconductor wafer 100. A series of development processes are completed in this way.

According to the method for manufacturing the semiconductor device according to one embodiment of the present invention, the development processing is carried out from the chip side in which the draw-and-lay time from after exposure up to PEB, i.e., the chip side in which exposure has finally been done. Thus, since the developing time is set long to each chip short in draw-and-lay time and the developing time is set short to each chip long in draw-and-lay time, the differences among the pattern dimensions due to PED (diffusion) in the wafer can be canceled out. In the development processing method of the scan system in particular, the scan direction of the developer supply nozzle 5 is adjusted in such a manner that the development processing is done from the chip side in which exposure has finally been carried out. Consequently, the differences among the pattern dimensions due to PED (diffusion) can be canceled out by the development processing. Thus, it is possible to reduce the difference in pattern dimension in the same wafer and form the semiconductor device with satisfactory accuracy. It is also possible to improve manufacturing yields.

According to the apparatus for manufacturing the semiconductor device according to one embodiment of the present invention, it is equipped with the detector 4, which detects the orientation flat (OF) or notch of the semiconductor wafer 100. Therefore, the semiconductor wafer 100 can always be stopped on the spin chuck 2 as viewed in a predetermined direction. Thus, it is possible to realize the development processing method having taken into consideration the order of exposure of the semiconductor wafer 100, e.g., a development processing method of the present invention, which causes a developer supply nozzle 5 to be scanned in a predetermined direction from the orientation flat (OF) side to the side opposite to the orientation flat (OF) or the side opposite to the orientation flat (OF) to the orientation flat (OF) side with the orientation flat (OF) as the reference.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. It is therefore contemplated that the appended claims will cover any such modifications or embodiments as fall within the true scope of the invention.

What is claimed is:

1. A method for manufacturing a semiconductor device, comprising the steps:
a resist deposition step for forming a resist film on the surface of a semiconductor substrate provided with a plurality of chips disposed in matrix form;
an exposure step for sequentially exposing chip patterns with respect to the respective chips in a predetermined exposure order from the chip set as a starting point of the semiconductor substrate; and
a development step for developing the respective chips in the order opposite to the exposure order from the chip set as an end point in the exposure order.

2. The method according to claim 1, wherein the resist film is a chemical amplifying resist film.

3. The method according to claim 2, wherein the development step performs development while a developer supply nozzle is being moved so as to be scanned over the semiconductor substrate.

4. The method according to claim 3, wherein the development step performs development in such a manner that variations in dimension among resist patterns due to differences in draw-and-lay time caused by the exposure order between the chip set as the starting point and the chip set as the end point are canceled out by variations in dimension among the resist patterns due to differences in developing time between the chip set as the starting point and the chip set as the end point.

5. The method according to claim 4, wherein the development step further adjusts a scan speed of the developer supply nozzle and thereby performs development processing, and the scan speed is adjusted such that a scan is done in a developing time equivalent to a difference in dimension caused by the difference in drawn-and-lay time caused by the exposure order between the chip set as the starting point and the chip set as the end point.

6. A method for manufacturing a semiconductor device, comprising the steps:
a resist deposition step for forming a resist film on the surface of a semiconductor substrate equipped with a plurality of chip rows disposed in matrix form in first and second directions orthogonal to each other;
an exposure step for repeatedly exposing the respective chip rows in the second direction in parallel to one chip row in a predetermined exposure order from the one chip row set as a starting point in parallel to the first direction of the semiconductor substrate; and
a development step for developing the respective chip rows in the second direction in the order opposite to the exposure order from one chip row set as an end point in parallel to the first direction in the exposure order.

7. The method according to claim 6, wherein the resist film is a chemical amplifying resist film.

8. The method according to claim 7, wherein the development step performs development while a developer supply nozzle is being moved so as to be scanned over the semiconductor substrate.

9. The method according to claim 8, wherein the development step performs development in such a manner that variations in dimension among resist patterns due to differences in draw-and-lay time caused by the exposure order between the one chip row set as the starting point and the one chip row set as the end point are canceled out by variations in dimension among the resist patterns due to differences in developing time between the one chip row set as the starting point and the one chip row set as the end point.

10. The method according to claim 9, wherein the development step further adjusts a scan speed of the developer supply nozzle and thereby performs development processing, and the scan speed is adjusted such that a scan is done in a developing time equivalent to a difference in dimension caused by the difference in drawn-and-lay time caused by the exposure order between the one chip row set as the starting point and the one chip row set as the end point.
